(19) United States
(12) Patent Application Publication
(10) Pub. No.: US 2018/0376606 A1
(43) Pub. Date: Dec. 27, 2018

(54) SYSTEM FOR MOUNTING SENSORS

(71) Applicant: Richard Kozdras, Morriston (CA)

(72) Inventor: Richard Kozdras, Morriston (CA)

(21) Appl. No.: 15/936,972

(22) Filed: Mar. 27, 2018

Related U.S. Application Data
(60) Provisional application No. 62/525,333, filed on Jun. 27, 2017.
(60) Provisional application No. 62/476,946, filed on Mar. 27, 2017.
(60) Provisional application No. 62/487,141, filed on Apr. 19, 2017.
(60) Provisional application No. 62/504,190, filed on May 10, 2017.
(60) Provisional application No. 62/522,286, filed on Jun. 20, 2017.
(60) Provisional application No. 62/488,950, filed on Apr. 24, 2017.

(51) Int. Cl. H05K 5/02; H05K 7/14

(52) U.S. Cl. CPC H05K 5/0286; H05K 7/1401; H05K 5/0217; H05K 5/0204

(57) ABSTRACT

A kit for use with a wireless sensor includes a backer plate having a pair of apertures spaced apart 3.25″ from one another and a cover plate, the cover plate being adapted to be secured to the backer plate and being provided with an adaptation which allows for ready receipt of the wireless sensor.

### CROSS-REFERENCE TO RELATED APPLICATIONS

This application claims the benefit of U.S. provisional patent application Ser. No. 62/525,333, filed on Jun. 27, 2017, and U.S. provisional patent application Ser. No. 62/476,946, filed on Mar. 27, 2017, and U.S. provisional patent application Ser. No. 62/487,141, filed on Apr. 19, 2017, and U.S. provisional patent application Ser. No. 64/488,950, filed on Apr. 24, 2017, and U.S. provisional patent application Ser. No. 62/504,190, filed on May 10, 2017, and U.S. provisional patent application Ser. No. 62/522,286, filed on Jun. 20, 2017, all of which are incorporated by reference as if completely written herein.

### STATEMENT REGARDING FEDERALLY SPONSORED RESEARCH OR DEVELOPMENT

Not applicable.

### TECHNICAL FIELD

The invention relates to the field of sensors.

### BACKGROUND OF THE INVENTION

Great advances are being made in the construction of wireless sensors. However, the rate of adoption of these sensors could be improved.

### SUMMARY OF THE INVENTION

Forming one aspect of the invention is a kit for use with a wireless sensor, the kit comprising: a backer plate having a pair of apertures spaced apart 3.25″ from one another; and a cover plate, the cover plate being adapted to be secured to the backer plate and provided with an adaptation which allows for ready receipt of the wireless sensor.

According to another aspect, the kit can further comprises a strip of double-sided tape; and the backer plate can have (i) a planar back surface and (ii) a boss surface arranged substantially coplanar with the back surface and spaced therefrom a distance less than the thickness of the tape, whereby the double-sided tape can be applied to the back surface and to a planar substrate to retain the boss surface in abutting relationship to the planar substrate. According to another aspect: the kit can further comprise a plurality of magnets; and the backer plate can have defined therein, for each of the plurality of magnets, a socket presenting opposite to the planar back surface and adapted to receive said each magnet, whereby the magnets can be fitted in the sockets to retain the backer plate to a planar metallic substrate.

According to another aspect, the kit can further comprising a pair of pipe clamps; and the backer plate can be adapted for receipt of the pipe clamps, whereby the pipe clamps can be secured to the backer plate to retain the backer plate to a pipe. According to another aspect, the adaptation can be a plurality of pin holes defined in the cover plate.

Other advantages, features and characteristics of the present invention will become evident upon a review of the following detailed description with reference to the appended drawings, the latter being briefly described hereinafter.

### BRIEF DESCRIPTION OF THE DRAWINGS

FIG. 1A is a component of a system according to an exemplary embodiment of the invention as described in the accompanying specification;

FIG. 1B is another component of a system according to an exemplary embodiment of the invention as described in the accompanying specification;

FIG. 1C is another component of a system according to an exemplary embodiment of the invention as described in the accompanying specification;

FIG. 1D is another component of a system according to an exemplary embodiment of the invention as described in the accompanying specification;

FIG. 1E is another component of a system according to an exemplary embodiment of the invention as described in the accompanying specification;

FIG. 1F is another component of a system according to an exemplary embodiment of the invention as described in the accompanying specification;

FIG. 2 is another view of the components of FIG. 1 as described in the accompanying specification;

FIG. 3 is another view of the components of FIG. 1A and FIG. 1D as described in the accompanying specification;

FIG. 4 is another view of the components of FIG. 1A and FIG. 1E as described in the accompanying specification;

FIG. 5 is another view of the components of FIG. 1A and FIG. 1C as described in the accompanying specification;

FIG. 6 is another view of the components of FIG. 1A and FIG. 1F as described in the accompanying specification;

FIG. 7 is another view of the components of FIG. 1A and FIG. 1B as described in the accompanying specification;

FIG. 8A is a view of a tool according to another aspect of the invention;

FIG. 8B is another view of the tool of FIG. 8A;

FIG. 9 is a side view of a clamp that forms another aspect of the invention;

FIG. 10 is a view of the structure of FIG. 9 in use with the structure of FIG. 2;

FIG. 11 is a view of a solar apparatus that forms another aspect of the invention;

FIG. 12 is a view of the structure of FIG. 11 in use with the structure of FIG. 7;

FIG. 13A is a view of a bracket that forms another aspect of the invention;

FIG. 13B is another view of a bracket that forms another aspect of the invention;

FIG. 14 is a view of the structure of FIG. 13 coupled to a prior art bar clamp;

FIG. 15 is a view of a flexible mount from one aspect of the invention; and

FIG. 16 is a view of an adaptor allowing for sensors to be easily mounted in a wide variety of locations.

### DETAILED DESCRIPTION OF THE INVENTION

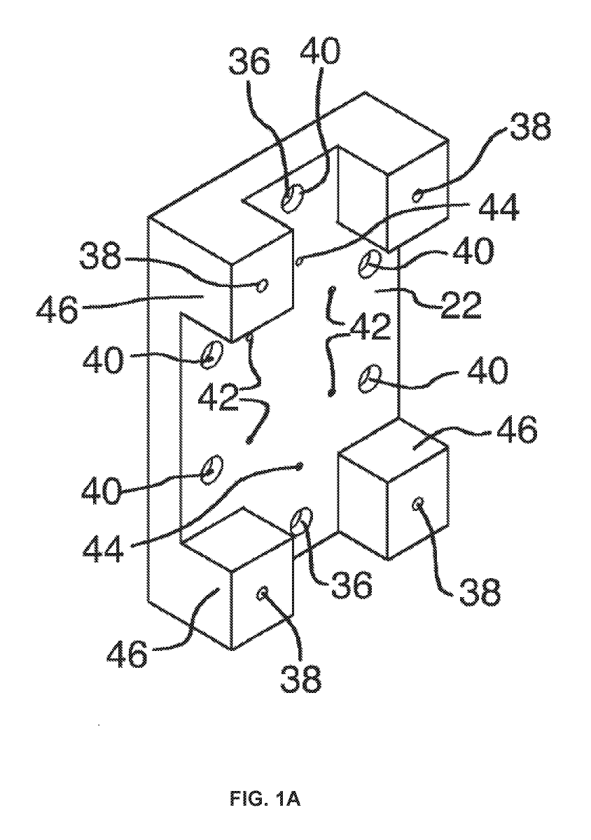

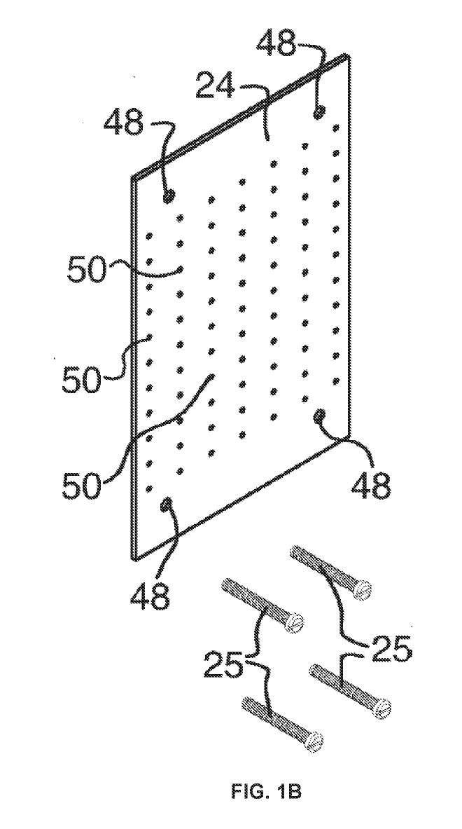

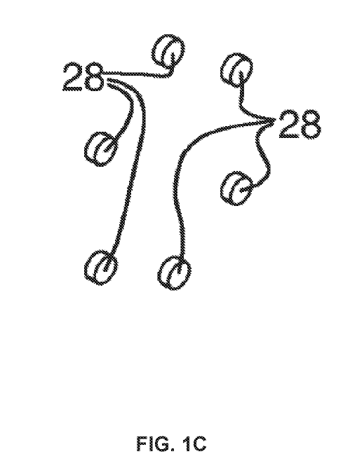

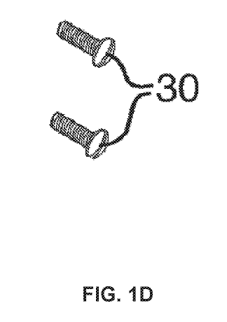

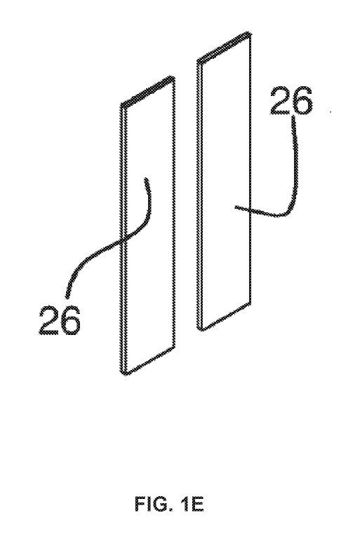

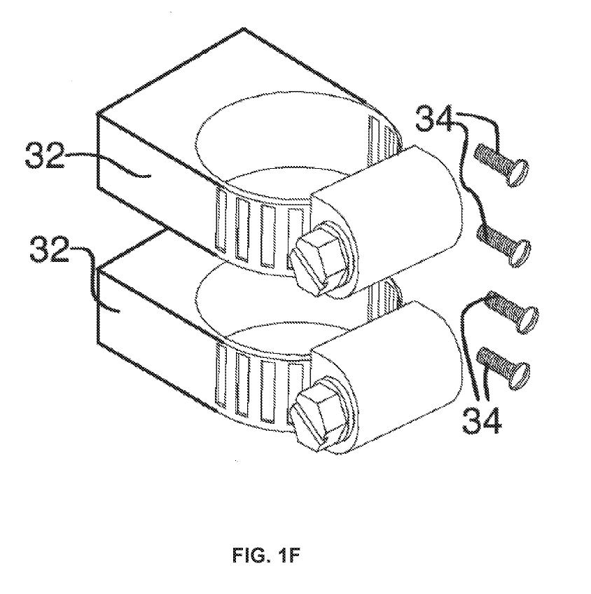

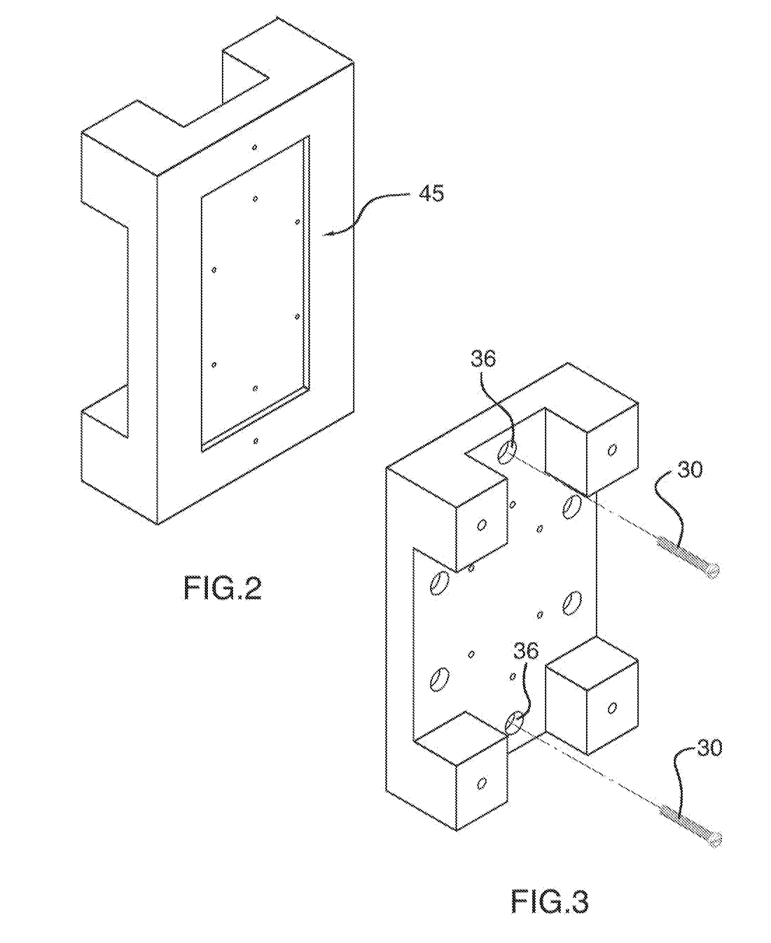

Forming one aspect of the invention is a system. As indicated in FIG. 1A-1F and FIG. 2, the system (20) comprises the following components: backer plate (22), cover plate (24), cover plate mounting screws (25), strips (26), magnets (28), backer mounting screws (30), pipe clamps (32), clamp mounting screws (34).

The backer plate (22) has a pair of mounting holes (36), four bores (38), six sockets (40), four apertures (42), two voids (44) and a hollow (45). The bores (38) are defined in protruding posts (46). The cover plate (24) has four apertures (48) and a plurality of pin holes (50). The cover plate mounting screws (25) are sized to permit passage through apertures (48) and to be threadingly received by bores (38). The strips (26) are each defined by double-side tape. The magnets (26) are Neodymium and are sized for receipt by sockets (40). The backer mounting screws (30) are sized to permit passage through holes (36). The pipe clamps (32) have sockets defined therein (not shown). The clamp mounting screws (34) are adapted to pass through apertures (42) and be threadingly received by the sockets of the pipe clamps (32).

The system facilitates mounting of sensors in industrial facilities through the use of the backer plate:

FIG. 3 shows screws (30) arranged so as to mount the backer plate to a conventional electrical receptacle box.

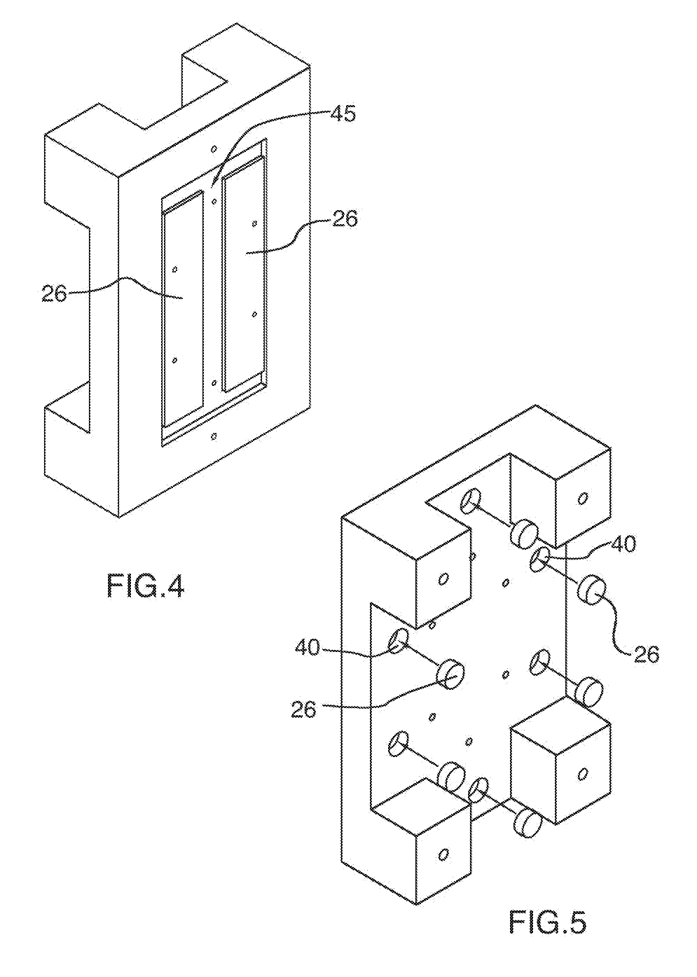

FIG. 4 shows double-sided tape strips secured in the hollow (45), thereby to allow the backer plate to be adhesively mounted to a wall or other planar surface.

FIG. 5 shows magnets (26) arranged for receipt by sockets, to mount the backer plate to a metal planar surface, such as a cabinet.

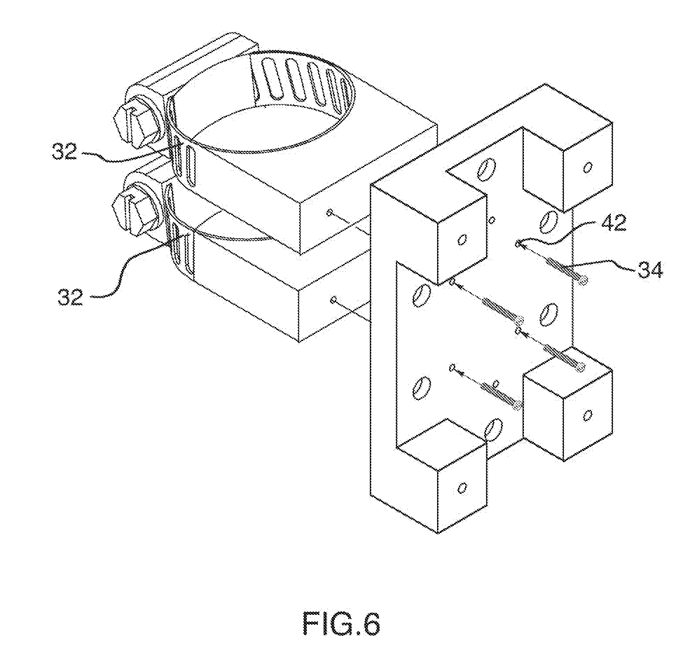

FIG. 6 shows clamp mounting screws (34) positioned for passage through apertures (42) into the sockets of the pipe clamps (32), thereby to allow the bracket to be mounted to a pipe or the like. Backer plate can also be mounted to a wood or similar surface by screws or the like driven through voids (44), not shown.

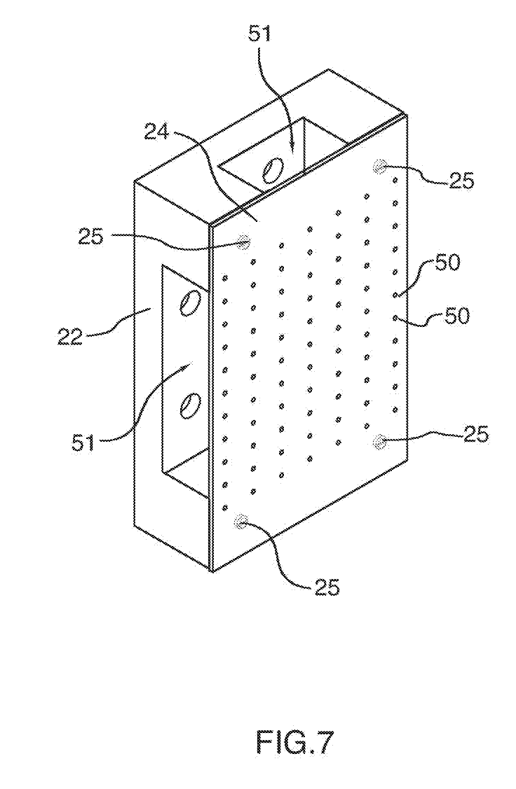

FIG. 7 shows the manner in which the backer plate (22) is used, namely, to provide a mounting surface for the cover plate (24), which is secured in place via cover plate mounting screws (25) which engage bores 38. The pin holes (50) allow for sensors from a broad variety of manufacturers to be conveniently mounted to the cover plate. FIG. 7 also shows channels (50) that are defined when the cover is so secured.

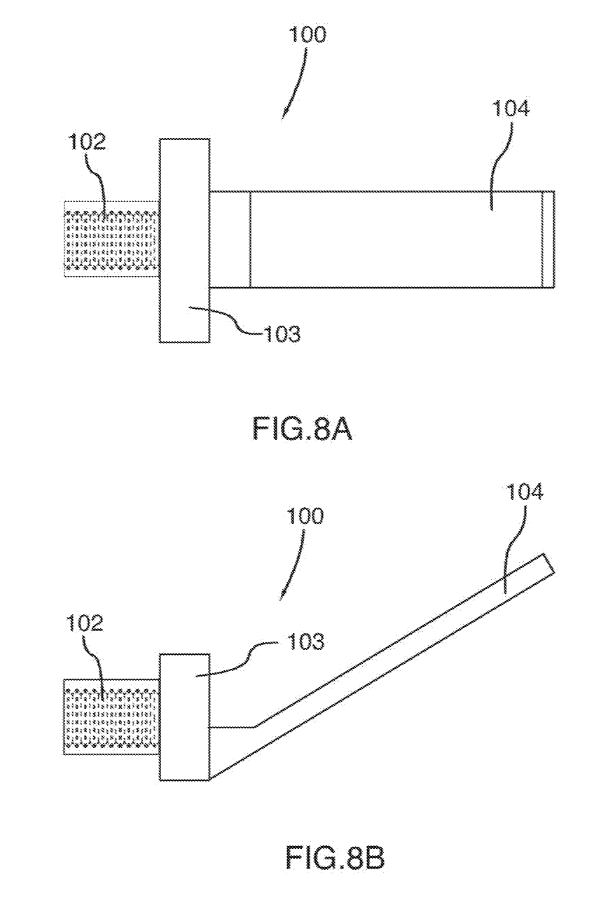

FIGS. 8A, 8B show a tool (100) that enables the assembly of FIG. 7 (when functionalized with the magnets or the tape) to be easily positioned at elevated locations. Tool (100) will be seen to have a threaded end (102), an abutment (103) and an angularly projecting finger (104).

To mount the assembly, one merely threads the tool on a telescopic pole, of the type used for paint rollers and the like, fits the assembly such that the finger (104) projects into one of the channels (50), and places the assembly as desired, to be held by the magnets or tape as desired. The assembly can be removed, for service and the like, by fitting the finger (104) into the channel until such time as the abutment engages, and then pivoting the assembly, to separate the tape/magnet from the substrate.

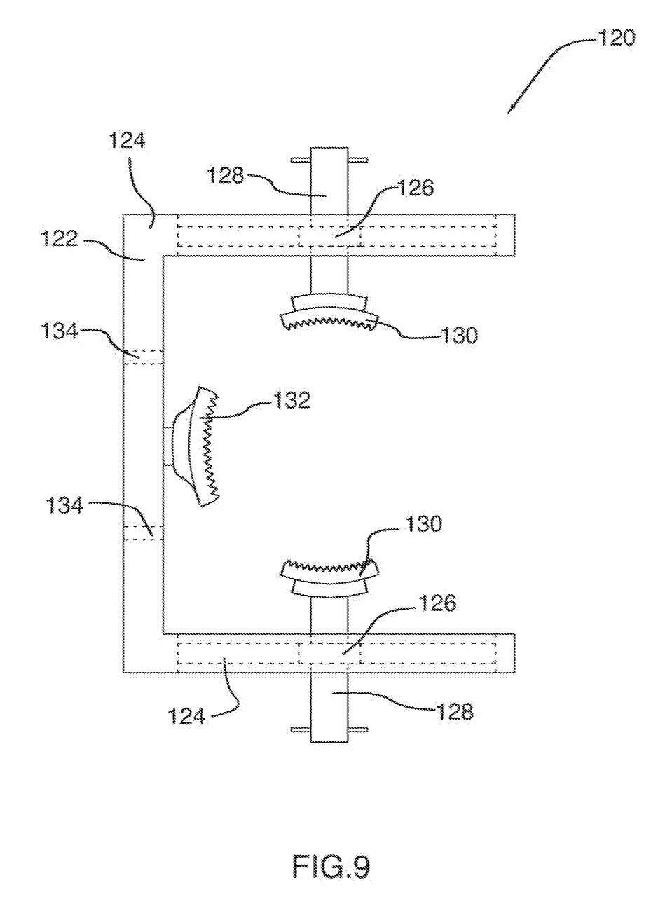

FIG. 9 shows a clamp (120) that forms another inventive aspect of the invention. The clamp has a C-shaped body (122). In the opposed arms of the body (122), passages (124) are defined, each passage having captured therein a caged nut (126). Through each caged nut, a turnscrew (128) extends, terminating in an arcuate pad (130). A further arcuate pad (132) projects from the body, intermediate the arms. Threaded bores (134) are defined in flanking relation to the pad (132).

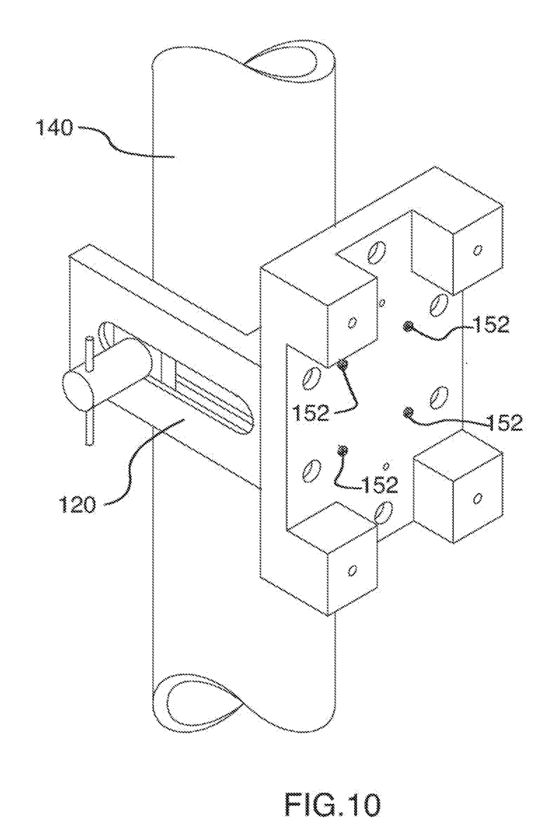

In occasions when the assembly needs to be mounted to, for example, an oversized pipe, the clamp can be utilized, as suggested by FIG. 10, wherein the clamp (120) is shown affixed to a pipe (140) and the structure of FIG. 2 is shown secured to the clamp by screws (152) that engaged threaded bores (134). Although not easily seen, it will be understood that the pads (130,132) have variable radii, thereby to enable the pads to grip pipes of a broad range of diameters.

FIG. 11 shows a solar collector (160) that forms another aspect of the invention. The collector (160) is generally cubic, with photovoltaic cells (162) on five of the six faces thereof. A pair of mounting flanges (164) extend from the sixth face. A USB jack (166) is provided on the collector (160) and is mounted to the cells via an intermediate battery, not shown.

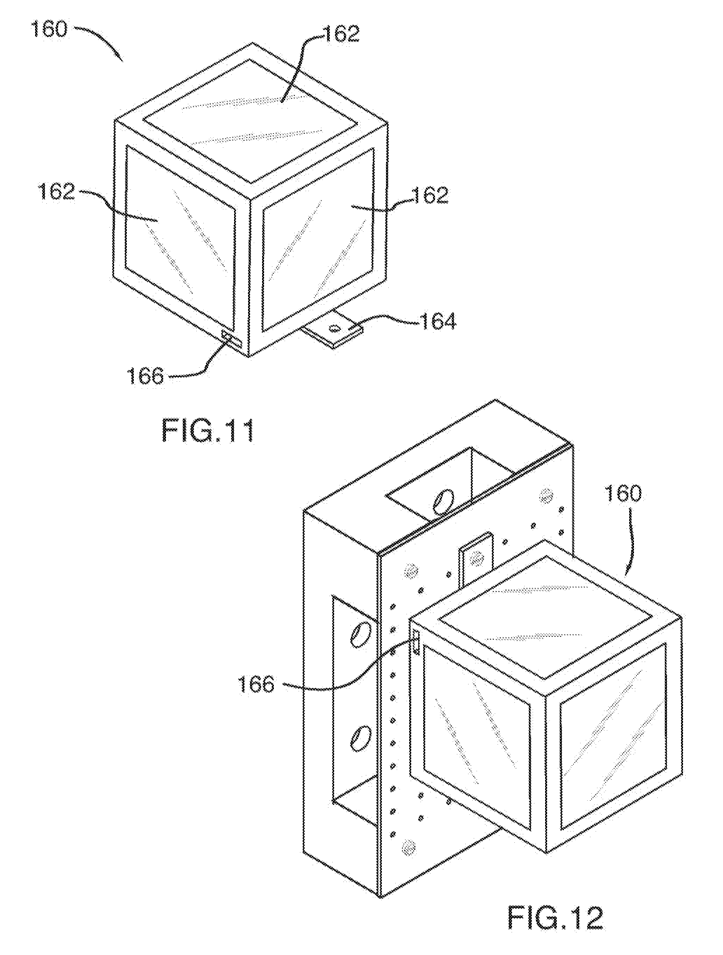

The mounting flanges (164) permit the collector (160) to be easily mounted to the structure of FIG. 7, as shown in FIG. 12. The structure of FIG. 12 provides a convenient mechanism to power sensors, when grid power is not easily available and battery exchange is inconvenient: the structure of FIG. 12 can be mounted adjacent the sensor to be powered and in an area where light can be gathered, either from interior lights of the facility or from the sun, and a connection can be made from the structure to the sensor using the jack (160) [none of the foregoing shown]. In an exemplary arrangement [not shown] the sensor housing will itself have a USB jack that can be used or receive external battery power or can be used to receive another sensor, and the connection between the cube (160) and a sensor to be powered can be a simple plug-and-play connection between the USB jack (166) of the collector (160) and the USB jack of the sensor. The USB jack (166) will also allow the solar collector (160) to be provided with firmware updates from time to time.

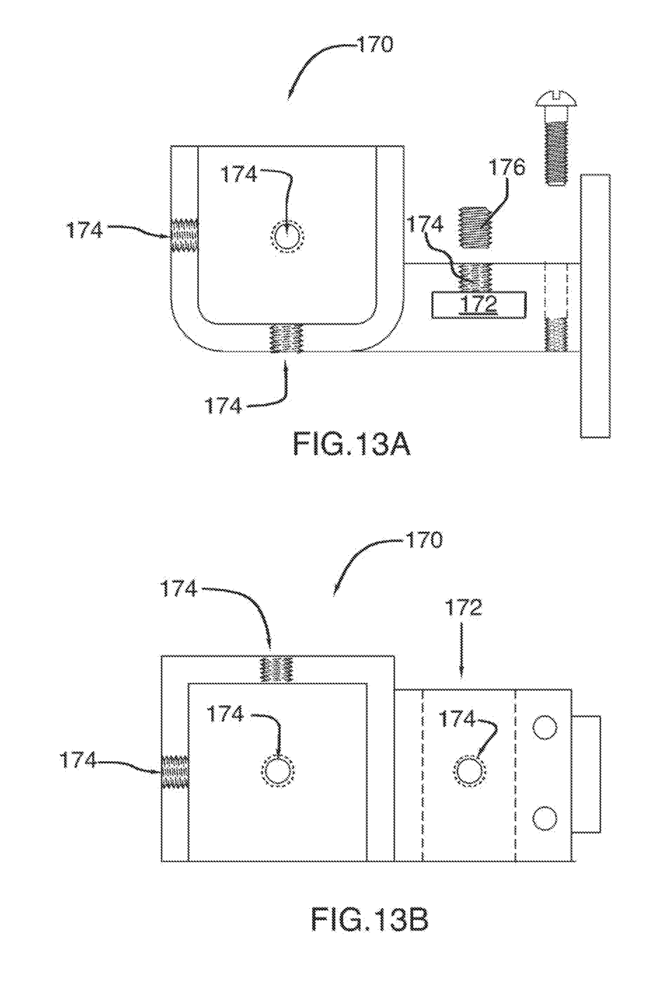

Forming yet another aspect of the invention is a bracket, an exemplary embodiment thereof being shown in FIGS. 13A,13B and designated with general reference (170). The bracket (170) will be seen to define a channel (172), to have a threaded socket (174) extending into the channel (172), and to have a plurality of threaded bores (174) provided thereon. A set screw (176) is also provided.

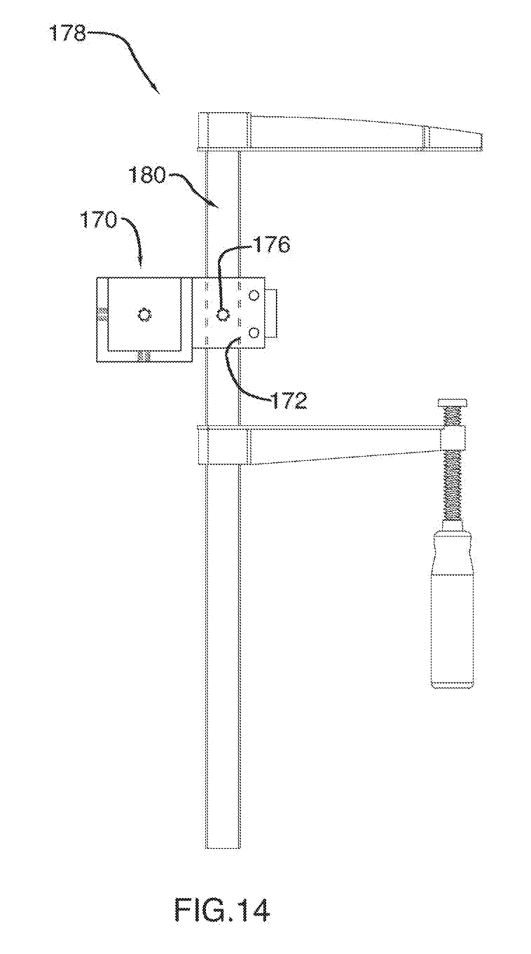

The bracket (170) and set screw (176) are shown assembled to a prior art bar clamp (178) in FIG. 14. Herein, it will be seen that the bar (180) of the bar clamp (178) extends through the channel (172) and gripped by the set screw (176). The bracket (170) provides yet another means for mounting sensors to, for example, tables: a simple prior art bar clamp can be secured to the table, the bracket can be secured to the bar clamp and threaded fasteners can be driven through the sensor and into the threaded bores (174) (not shown), or, where the sensor itself terminates in a threaded shaft, the shaft can be fitted into the threaded bores (not shown).

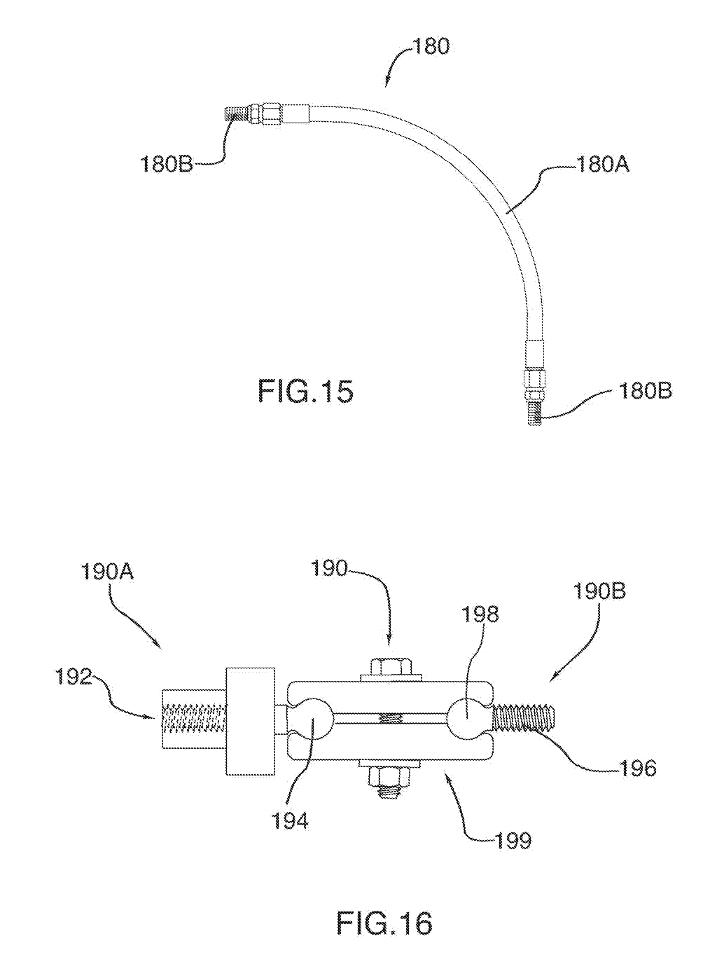

FIG. 15 shows a flexible mount arrangement (180) that can be used with bracket (170). Arrangement (180) has a length (180A) of flexible tubing, with threaded mounting studs (180B) at each end. One of the threaded mounting studs can be fitted through one of the bores (174) of the bracket (170) and secured in place with a lock washer and a nut (not shown). The other of the threaded mounting studs can be used for securement of the sensor (if the sensor has a suitably threaded bore it can be threaded thereon; alternatively, the threaded studs can be fitted through a suitable aperture in the sensor and received by a nut—not shown).

FIG. 16 shows an adapter (190). The adapter (190) will be seen to have: at one end (190A), a portion defining a female threaded socket (192) and also carrying a ball (194); at the other end (190B), a portion defining a threaded stud (196) and also carrying a ball (198); and a clamp structure (199) having, for each ball, a socket structure, adapted to selectively grip the ball. Persons of ordinary skill will readily appreciate that the threaded female socket of the adapter can be threaded to the free end of the mount arrangement (180), and the threaded stud of the adapter can be secured to a sensor, in the manner previously discussed, to provide for further articulation of the flexible mount.

Yet another aspect of the invention is a method for powering a sensor. In this method, a photovoltaic cell structure is placed interiorly of the housing of a standard tubular light fixture or lamp shade and coupled to the sensor, and to the extent necessary to offset light absorbed by the cells, the light tubes of the fixture are replaced with tubes of higher luminance. It will be evident that this methodology avoids the need for transformers or the like while allowing sensors to be placed easily in close proximity to light fixtures.

Yet another aspect of the invention is a method for powering a sensor. In this method, a suitable transformer or converter is provided in a form factor suitable to be mated to the knock-out that is commonly available in a standard tubular light fixture, coupled to the sensor and seated in the knock-out. It will be evident that this methodology allows sensors to be placed easily in close proximity to light fixtures.

Yet another aspect of the invention is an inductive charging plate disposed in the cover plate or the backer plate and operatively coupled to a power source including but not limited to the photovoltaic cell structure and the transformer indicated above. It will be evident that this methodology allows for sensors of widely-varying current needs to be relatively-easily mounted in a wide variety of locations.

Whereas specific embodiments are herein shown, it will be evident that variations are possible. Without limitation, whereas variants of the sensor are described wherein jacks or ports are provided to receive power from an external power source which itself contains photovoltaics to receive power from sunlight or artificial light, it will be appreciated that this is not necessary, and the external photovoltaic power source could, for example, terminate in structure that is adapted to be fitted into a sensor in the manner of a battery.

Similarly, whereas the external module described specifically mentions photovoltaics, other mechanisms for wireless transmission of energy, focused or otherwise, could be utilized. Further, whereas a photovoltaic structure is mentioned, it will be understood that this could include one or many solar cells.

Accordingly, this aspect of the invention should be understood as to encompass at least any system which includes sensors that are adapted to be self-powered for a relatively short period of time and power units that receive power wirelessly and are releasably coupled by wires to said sensors to deliver said power thereto to adapt said sensors for operation for a relatively longer period of time.

I claim:

1. A kit for use with a wireless sensor, the kit comprising:
a backer plate having a pair of apertures spaced apart 3.25″ from one another;
a cover plate, the cover plate adapted to be secured to the backer plate and provided with an adaptation which allows for ready receipt of the wireless sensor.

2. The kit according to claim 1,
further comprising a strip of double-sided tape; and
wherein the backer plate has
a planar back surface and
a boss surface arranged substantially coplanar with the back surface and spaced therefrom a distance less than the thickness of the tape
whereby the double-sided tape can be applied to the back surface and to a planar substrate to retain the boss surface in abutting relationship to the planar substrate.

3. The kit according to claim 1,
further comprising a plurality of magnets; and
wherein the backer plate has defined therein, for each of the plurality of magnets, a socket presenting opposite to the planar back surface and adapted to receive said each magnet,
whereby the magnets can be fitted in the sockets to retain the backer plate to a planar metallic substrate.

4. The kit according to claim 1,
further comprising a pair of pipe clamps; and
wherein the backer plate is adapted for receipt of the pipe claims,
whereby the pipe clamps can be secured to the backer plate to retain the backer plate to a pipe.

5. The kit according to claim 1, wherein the adaptation is a plurality of pin holes defined in the cover plate.
